(19) United States
(12) Patent Application Publication
(10) Pub. No.: US 2024/0165746 A1
(43) Pub. Date: May 23, 2024

(54) SUBSTRATE MANUFACTURING DEVICE

(71) Applicant: HAMAMATSU PHOTONICS K.K., Hamamatsu-shi, Shizuoka (JP)

(72) Inventors: Atsushi TANAKA, Nagoya-shi, Aichi (JP); Hadi SENA, Nagoya-shi, Aichi (JP)

(73) Assignee: HAMAMATSU PHOTONICS K.K., Hamamatsu-shi, Shizuoka (JP)

(21) Appl. No.: 18/279,270

(22) PCT Filed: Feb. 28, 2022
(86) PCT No.: PCT/JP2022/008225

§ 371 Date: Aug. 29, 2023

(30) Foreign Application Priority Data
Mar. 2, 2021 (JP) 2021-032709

(51) Int. Cl. B23K 26/53; B23K 26/00; B23K 26/03; B23K 26/06; B23K 26/0622; B23K 26/082; B23K 103/00; B28D 5/00

(52) U.S. Cl. CPC B23K 26/53; B23K 26/0006; B23K 26/03; B23K 26/0617; B23K 26/0622; B23K 26/082; B23K 2103/56; B28D 5/0011

(57) ABSTRACT

A substrate manufacturing apparatus includes a stage on which a semiconductor substrate is disposed. The substrate manufacturing apparatus includes an irradiation unit that irradiates the semiconductor substrate disposed on the stage with a pulsed laser of a predetermined pulse period. The substrate manufacturing apparatus includes a controller that controls a relative position between the stage and the irradiation unit. The irradiation unit generates a plurality of converging points arranged on a straight line at a predetermined pitch. The controller moves the relative position between the stage and the irradiation unit at a predetermined speed in parallel to the straight line on which the plurality of converging points are arranged. The predetermined speed is a speed at which a moving distance of the plurality of converging points in one period of the predetermined pulse period is the same as the predetermined pitch.

### TECHNICAL FIELD

The present disclosure relates to a substrate manufacturing apparatus.

### BACKGROUND ART

Patent Literature 1 discloses a method of producing a gallium nitride substrate from a gallium nitride ingot. Specifically, a modified region where gallium and nitrogen precipitate is formed by irradiating a constant depth inside the gallium nitride ingot with a pulsed laser while scanning a converging point of the pulsed laser at a constant speed. An interface is formed by forming a plurality of the modified regions on a plane. The ingot is separated from an interface by heating the ingot at a temperature at which gallium is melted and by moving a first retainment member and a second retainment member in directions opposite to each other, thereby producing the gallium nitride substrate.

### CITATION LIST

### Patent Literature

Patent Literature 1: Japanese Unexamined Patent Publication No. 2017-57103

### SUMMARY OF INVENTION

### Technical Problem

It is necessary to increase the total amount of energy applied to an irradiation point in order to reliably form the modified region. However, when increasing a laser output, large energy is applied to the irradiation point with single irradiation, and thus unintended cracks and the like may occur. Surface roughness of the separated gallium nitride substrate may become large.

### Solution to Problem

A substrate manufacturing apparatus according to an aspect of the present disclosure includes a stage on which a semiconductor substrate is disposed. The substrate manufacturing apparatus includes an irradiation unit that irradiates the semiconductor substrate disposed on the stage with a pulsed laser of a predetermined pulse period. The substrate manufacturing apparatus includes a controller that controls a relative position between the stage and the irradiation unit. The irradiation unit generates a plurality of converging points arranged on a straight line at a predetermined pitch. The controller moves the relative position between the stage and the irradiation unit at a predetermined speed in parallel to the straight line on which the plurality of converging points are arranged. The predetermined speed is a speed at which a moving distance of the plurality of converging points in one period of the predetermined pulse period is the same as the predetermined pitch.

In the substrate manufacturing apparatus according to the aspect of the present disclosure, the plurality of converging points are moved in a straight line direction on which the plurality of converging points are arranged. In addition, the moving distance of the plurality of converging points in one period of a predetermined pulse period is equal to a predetermined pitch. According to this, the same irradiation point can be irradiated with the plurality of converging points of the pulsed laser. Therefore, energy can be applied to the same irradiation point by the plurality of converging points in a state of being divided into a plurality of times. In comparison to a case where energy is applied to the irradiation point by single irradiation, it is possible to further reduce a laser output per irradiation performed once while the total amount of energy to be applied is set to be equal to or larger. Occurrence of unintended cracks and the like can be suppressed.

The irradiation unit may include a plurality of laser light sources. The plurality of converging points may be generated by the plurality of laser light sources.

Pulse energy of some converging points among the plurality of converging points may be different from pulse energy of the other converging points.

Among the plurality of converging points, pulse energy of converging points on a front side in a traveling direction along which the plurality of converging points are moved by the controller may be smaller than pulse energy of converging points on a rear side in the traveling direction.

Among the plurality of converging points, pulse energy of converging points on a front side in a traveling direction along which the plurality of converging points are moved by the controller may be larger than pulse energy of converging points on a rear side in the traveling direction.

A pulse width of some converging points among the plurality of converging points may be different from a pulse width of the other converging points.

Among the plurality of converging points, the pulse width of converging points on a front side in a traveling direction along which the plurality of converging points are moved by the controller may be smaller than the pulse width of converging points on a rear side in the traveling direction.

Among the plurality of converging points, the pulse width of converging points on a front side in a traveling direction along which the plurality of converging points are moved by the controller may be larger than the pulse width of converging points on a rear side in the traveling direction.

A wavelength of some converging points among the plurality of converging points may be different from a wavelength of the other converging points.

Among the plurality of converging points, the wavelength of converging points on a front side in a traveling direction along which the plurality of converging points are moved by the controller may be larger than the wavelength of converging points on a rear side in the traveling direction.

Among the plurality of converging points, the wavelength of converging points on a front side in a traveling direction along which the plurality of converging points are moved by the controller is smaller than the wavelength of converging points on a rear side in the traveling direction.

A measurement unit that measures a modified region formed in the semiconductor substrate disposed on the stage by the plurality of converging points may be further provided. The irradiation unit may control the number of the plurality of converging points in correspondence with a measurement result obtained by the measurement unit.

The measurement unit measures a size of the modified region. The irradiation unit may perform control so that the number of the plurality of converging points further increases as the size of the modified region is smaller.

### Advantageous Effects of Invention

The present disclosure can provide a substrate manufacturing apparatus capable of suppressing occurrence of unintended cracks and the like.

### BRIEF DESCRIPTION OF DRAWINGS

FIG. 1 is a schematic structural diagram of a substrate manufacturing apparatus of a first embodiment.

FIG. 2 is a schematic view illustrating a plurality of converging points.

FIG. 3 is a schematic view illustrating a plurality of scanning lines.

FIG. 4 is a view illustrating an aspect in which the plurality of converging points move.

FIG. 5 is a flowchart illustrating a substrate manufacturing method of the first embodiment.

FIG. 6 is a view illustrating an example of an ingot in which a modified layer is formed.

FIG. 7 is a schematic structural diagram of a substrate manufacturing apparatus of a second embodiment.

### DESCRIPTION OF EMBODIMENTS

Hereinafter, embodiments of the present disclosure will be described in detail with reference to the accompanying drawings. Note that, in the respective drawings, the same reference numeral will be given to the same or equivalent portion, and redundant description will be omitted.

### First Embodiment

[Configuration of Substrate Manufacturing Device]

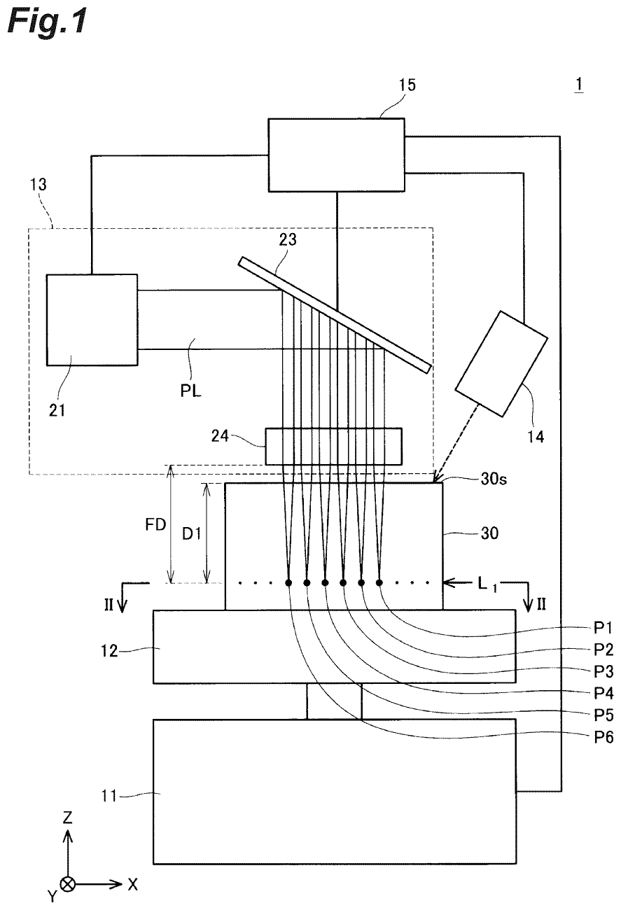

FIG. 1 is a schematic structural diagram of a substrate manufacturing apparatus 1. The substrate manufacturing apparatus 1 includes a stage drive unit 11, a stage 12, an irradiation unit 13, a measurement unit 14, and a controller 15. The stage drive unit 11, the irradiation unit 13, and the measurement unit 14 are controlled by the controller 15. For example, the controller 15 is a PC. An ingot (semiconductor substrate) 30 that is an object to be processed is disposed on the stage 12.

The irradiation unit 13 is a portion that irradiates the ingot 30 disposed on the stage 12 with a pulsed laser of a predetermined pulse period. The irradiation unit 13 includes a laser light source 21, a spatial optical modulator 23, and a converging lens 24. The laser light source 21 is a device that output laser light having a transmitting property with respect to the ingot 30. In the first embodiment, an oscillation frequency of the pulsed laser is 50 kHz (that is, the pulse period is 0.02 ins), and a wavelength of the pulsed laser is 532 nm.

The spatial optical modulator 23 is a device that modulates a phase of a pulsed laser PL output from the laser light source 21. In the first embodiment, the spatial optical modulator 23 is a reflective liquid crystal (liquid crystal on silicon (LCOS)) spatial optical modulator. It is possible to freely form a light beam pattern by the spatial optical modulator 23. In addition, the spatial optical modulator 23 can perform modulation of the pulsed laser PL so that pulse energy of some converging points among a plurality of converging points is different from pulse energy of the other converging points. In the first embodiment, modulation of the pulsed laser PL is performed so that six converging points P1 to P6 are formed as to be described later. Note that, the number of the converging points is freely changed, and is not limited to six. In addition, the pulse energy at the converging points can be set individually.

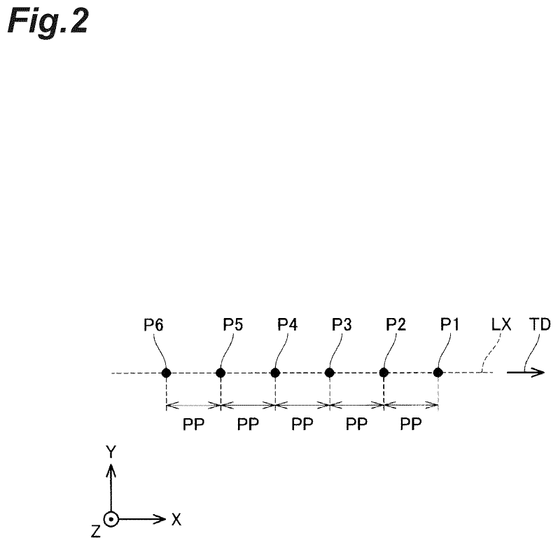

The converging lens 24 converges the pulsed laser modulated by the spatial optical modulator 23. According to this, six converging points P1 to P6 can be formed at positions separated from the converging lens 24 by a converging distance FD. FIG. 2 is a cross-sectional view of the ingot 30 at a depth where the plurality of converging points P1 to P6 are located. That is, FIG. 2 is a cross-sectional view of the ingot 30 on a surface in which a modified layer L₁ is formed. The converging points P1 to P6 are arranged on a straight line LX extending in an X direction. The irradiation unit 13 generates the plurality of converging points P1 to P6. The converging points P1 to P6 are arranged with even intervals at a predetermined pitch PP. In the first embodiment, the predetermined pitch PP is 5 μm, and peak outputs of the respective converging points P1 to P6 are the same value of 0.025 W.

The controller 15 can move the stage 12 in X, Y, and Z directions by controlling the stage drive unit 11. That is, the controller 15 controls a relative position between the stage 12 and the irradiation unit 13 by the stage drive unit 11. The controller 15 moves the relative position between the stage 12 and the irradiation unit 13 (in other words, a position of the irradiation unit 13 with respect to the stage 12, or a position of the stage 12 with respect to the irradiation unit 13) at a predetermined speed in parallel to the straight line LX on which the plurality of converging points P1 to P6 are arranged. The measurement unit 14 is a portion that measures a plurality of the modified regions MA formed inside the ingot 30. The modified regions MA will be described later. In the first embodiment, the measurement unit 14 is a camera.

[Scanning Processing of Converging Point]

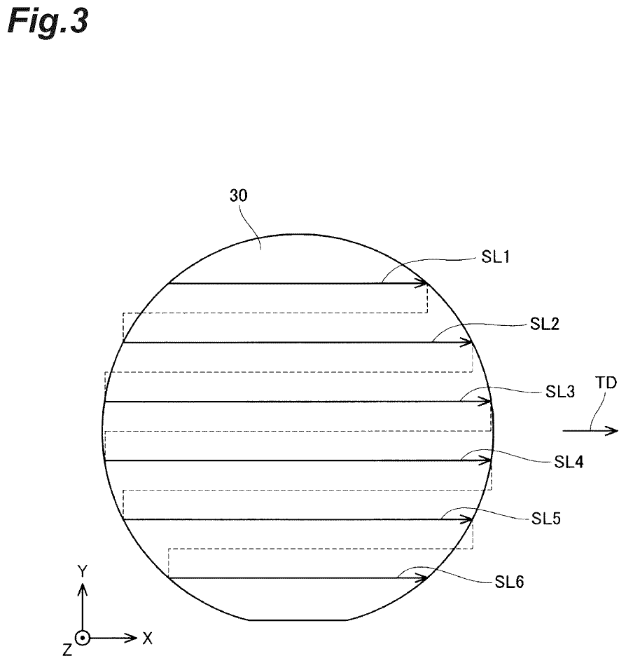

As illustrated in FIG. 3, the controller 15 can scan the converging points P1 to P6 on scanning lines SL1 to SL6 by controlling the stage drive unit 11. At the respective scanning lines SL1 to SL6, the converging points P1 to P6 illustrated in FIG. 2 can be moved in a traveling direction TD that is a +X direction by moving the stage 12 in a −X direction. That is, at the respective scanning lines SL1 to SL6, the converging points P1 to P6 move on the straight line LX on which the converging points P1 to P6 are arranged.

Scanning of the scanning lines SL1 to SL6 is performed at a predetermined speed. The predetermined speed is a speed at which a moving distance of the converging points P1 to P6 in one period (0.02 ins) of the pulsed laser becomes the same as the predetermined pitch PP (5 μm). In the first embodiment, the predetermined speed is 250 mm/s.

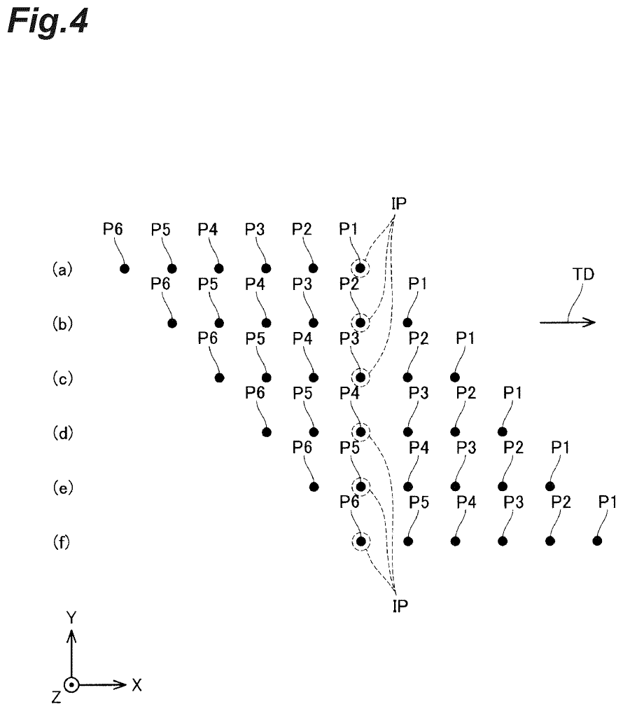

Description will be made with reference to FIG. 4. FIGS. 4(a) to 4(f) illustrate an aspect in which the converging points P1 to P6 move in the traveling direction TD per one period of the pulsed laser. Here, description will be made with a focus given to one certain irradiation point IP. In FIG. 4(a), first-time irradiation with the pulsed laser is performed on the irradiation point IP by the converging point P1. In FIG. 4(b) after passage of one period (0.02 ms), second irradiation with the pulsed laser is performed on the irradiation point IP by the converging point P2. In this manner, in FIG. 4(f) after passage of five periods (0.10 ms), sixth irradiation with the pulsed laser is performed on the irradiation point IP by the converging point P6. According to this, energy is applied by the six converging points P1 to P6 in a state of being divided into six times, and thus the modified region MA can be formed at the irradiation point IP. That is, the modified region MA can be formed by dividing steps into a seed forming step of forming a minute modified region MA (a seed of the modified region MA) and an expansion step of expanding the formed modified region MA. Then, the irradiation point IP can be formed in a state of being arranged on the scanning lines SL1 to SL6 at a predetermined pitch PP (5 μm).

As described above, pulse energy in each of the converging points P1 to P6 can be individually set by the spatial optical modulator 23. Accordingly, various settings of the pulse energy can be made. For example, pulse energy of the converging points P1 to P6 may be set to be equal (first energy setting). Pulse energy of a converging point on a front side in the traveling direction TD may be set to be smaller than pulse energy of a converging point on a rear side in the traveling direction TD (second energy setting). The pulse energy of the converging point on the front side in the traveling direction TD may be set to be larger than the pulse energy of the converging point on the rear side in the traveling direction TD (third energy setting). Since the peak output [W] is calculated by dividing the pulse energy [J] by a pulse width [s], in a case where the pulse width is constant, as the pulse energy is set to be larger, the peak output can be set to be larger. In the first energy setting, the integrated amount of energy can be linearly increased at each of a plurality of the irradiation points IP. In the second setting, the integrated amount of energy can be set to be smaller in the first half of irradiation, and can be set to be larger in the second half. In the third energy setting, the integrated amount of energy can be set to larger in the first half of irradiation, and can be set to be smaller in the second half.

Note that, in the second and third energy settings, a variation aspect of the pulse energy may be various. For example, the pulse energy may linearly vary as to goes toward a front side in the traveling direction TD, or the pulse energy may vary stepwise for each of the plurality of converging points.

[Substrate Manufacturing Method]

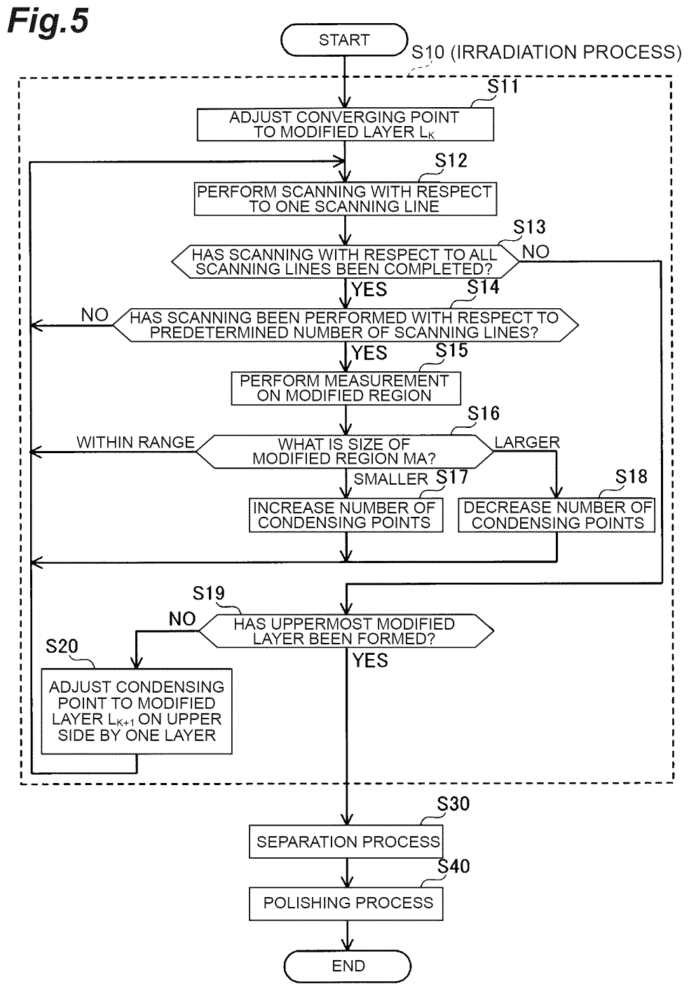

A substrate manufacturing method of the first embodiment will be described with reference to a flow in FIG. 5. The substrate manufacturing method includes an irradiation process in step S10, a separation process in step S30, and a polishing process in step S40.

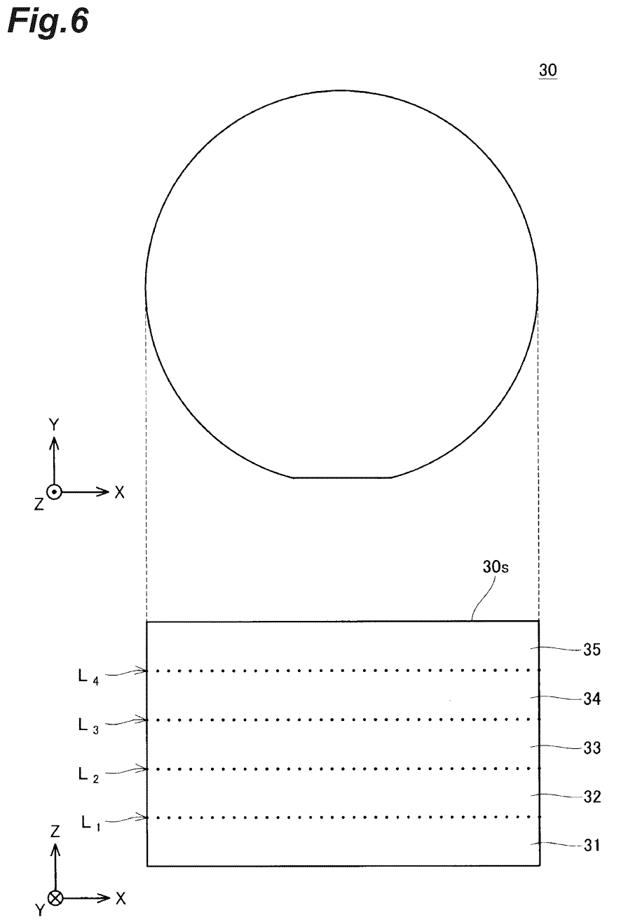

The irradiation process in step S10 will be described. The irradiation process is a process of forming N (N is a natural number of 1 or greater) modified layers in the ingot. FIG. 6 is a view illustrating an example of the ingot 30 in which the modified layer is formed by the irradiation process. FIG. 6 shows a top view and a side view of the ingot 30. In the first embodiment, description will be given of a case where the number of the modified layers is four. The ingot 30 is formed from a single crystal of gallium nitride (GaN). The GaN single crystal is colorless. Four modified layers L₁ to L₄ different in a depth from a surface 30s are formed in the ingot 30. The ingot 30 is divided into five substrate layers 31 to 35 by the four modified layers L₁ to L₄.

The modified layer is a layer in which a plurality of modified regions exist in an X-Y plane. The modified region is a region in which a density, a refractive index, mechanical strength, and other physical properties are different from those of a GaN crystal in an initial state. As to be described later, the modified region is a region that is formed when nitrogen in GaN becomes a gas and evaporates due to local heating by the converging points of the pulsed laser. In the modified region, gallium precipitates and the modified region has a black color.

The irradiation process in step S10 includes steps S11 to S19. In step S11, a Z direction height of the stage 12 is adjusted so that the converging points P locate at a depth where K^{th} (K is a natural number of 1 to N) modified layer L K is formed. In the example in FIG. 1, the lowest modified layer L₁ is a modified layer that is formed at a position of a depth D1 from the surface 30s.

In step S12, scanning is performed with respect to one scanning line (refer to FIG. 3). In step S13, a determination is made as to whether or not scanning with respect to all scanning lines has been completed. In a case where the determination is negative (S13: NO), the process proceeds to step S14. In step S14, a determination is made as to whether or not scanning has been performed with respect to a predetermined number of (for example, three) scanning lines determined in advance. In a case where the determination is negative (S14: NO), the process returns to step S12, and the subsequent scanning is performed. In a case where the determination is positive (S14: YES), the process proceeds to step S15, and measurement on the modified region is performed. According to this, measurement on the modified region can be performed every time at which scanning is performed predetermined number of times.

Measurement in step S15 is performed by using the measurement unit 14. For example, a plurality of modified regions MA are imaged by a camera, a captured image is subjected to image processing by the controller 15 to obtain a size of each of the plurality of modified regions, and an average value may be calculated.

In step S16, a determination is made as to whether or not the size of the modified region MA is within a predetermined allowable range. In a case where the size is within the allowable range, it is determined that the modified region MA is appropriately formed, and the process returns to step S12. Then, the subsequent scanning is performed.

On the other hand, in a case where the size of the modified region MA is smaller than the allowable range (S16: small), the process proceeds to step S17. In step S17, the number of the converging points is increased by adjusting the spatial optical modulator 23 without changing the pulse energy in each of the converging points. Returning to step S12, the subsequent scanning is performed. According to this, in the subsequent scanning or later, since the integrated amount of energy applied to the modified region MA can be increased, it is possible to enlarge the size of the modified region MA.

In addition, in a case where the size of the modified region MA is larger than the allowable range (S16: large), the process proceeds to step S18. In step S18, the number of the converging points is decreased by adjusting the spatial optical modulator 23 without changing the pulse energy in each of the converging points. In addition, returning to step S12, the subsequent scanning is performed. According to this, in the subsequent scanning or later, since the integrated amount of energy applied to the modified region MA can be decreased, it is possible to reduce the size of the modified region MA.

Note that, the increased number or the decreased number of the converging points is not limited to one. For example, two or more may be increased or decreased in correspondence with a difference value between the measured size of the modified region MA and the allowable range. That is, the irradiation unit 13 controls the number of the plurality of converging points in correspondence with a measurement result obtained by the measurement unit 14. The irradiation unit 13 may perform control so that the number of the plurality of converging points further increases as the size of the modified region MA is smaller.

When scanning with respect to all scanning lines is completed, termination is determined in step S13 (S13: YES), and the process proceeds to step S19.

In step S19, a determination is made as to whether or not the uppermost modified layer has been formed. In a case where the determination is negative (S19: NO), the process proceeds to S20, and the stage 12 is moved in a −Z direction so that the converging point P moves to a depth where a K+1th modified layer L_{K+1} is to be formed.

In addition, returning to S12, the subsequent modified layer L_{K+1} is formed. According to this, modified layers L₁ to L₄ are formed one by one in the order from the bottom. That is, from the modified layer L₁ located at a deepest position from the surface 30s to the modified layer L₄ located at a shallowest position are sequentially formed one by one. According to this, the presence of a previously formed modified layer does not hinder formation of the subsequent modified layer.

Then, in a case where the uppermost modified layer L₄ has been formed, a positive determination is made in step S19 (S19: YES), the irradiation process in step S10 is terminated, and the process proceeds to step S30.

In the separation process in step S30, heat or a stress is applied to the ingot 30 to cause cracks extending from a plurality of the modified regions MA formed in the modified layers L₁ to L₄ to propagate in an in-plane direction. According to this, it is possible to separate the substrate layers 31 to 35 of the ingot from each other with positions where the modified layers L₁ to L₄ are formed set as a boundary.

The process proceeds to the polishing process in step S40, and a front surface and a rear surface of each of the substrate layers 31 to 35 separated from each other are polished. According to this, a damage layer is removed and the surfaces can be planarized. For example, the polishing process may be performed by chemical mechanical polishing method (CMP).

### Effect

In order to raise flatness of the substrate surfaces formed by the separation, enlargement of the modified region MA has been examined. In the related art in which the modified region MA is formed by single laser irradiation, it is necessary to raise a laser output (to increase energy to be applied) for enlargement of the modified region MA. However, when increasing the energy that is applied in the single irradiation, a large amount of precipitation of gallium or rising of a precipitation position, and the like are likely to occur. These become the cause for occurrence of cracks or deterioration in the flatness of the substrate surfaces. In the substrate manufacturing apparatus 1, as illustrated in FIG. 4, energy can be applied by the plurality of converging points in a state of being divided into a plurality of times of irradiation. In comparison to a case where energy is applied by single irradiation, it is possible to further reduce energy per irradiation performed once while the total amount of energy to be applied is set to be equal to or larger. Accordingly, energy of each of the plurality of converging points can be reduced to a certain extent with which a large amount of precipitation of gallium does not occur. In addition, when energy is repetitively applied to the same site by the plurality of converging points, the modified region MA can be gradually formed. It is possible to enlarge the modified region MA while suppressing the large amount of precipitation of gallium, rising of the precipitation position, and the like.

In the related art, it is also possible to form the modified region MA by a plurality of times of irradiation when performing control of moving a table to the subsequent irradiation point after irradiating the same irradiation point with the pulsed laser predetermined number of times. However, typically, the table position control is difficult. For example, as in the first embodiment, consideration will be given to a case where irradiation with the pulsed laser is performed six times for each irradiation point by setting a pulse period to 0.02 ins and by setting a pitch between irradiation points to 5 μm. In this case, it is necessary to repetitively control the table so that the table moves by 5 μm for every 0.1 ins. In addition, movement time is 0.02 ins. The position control is difficult, and vibration or positional deviation also occurs. On the other hand, in the substrate manufacturing apparatus 1, the table may be caused to move at a constant speed. When the table is controlled at a constant speed, it is possible to sufficiently raise positional accuracy in comparison to the repetitive control as described above. Accordingly, it is possible to perform a plurality of times of laser irradiation to the same irradiation point with high accuracy.

In a case where energy is applied to GaN in a state of being divided into a plurality of times of laser irradiation, as described above, it is possible to perform processing by dividing steps into a seed forming step of forming a minute modified region MA (a seed of the modified region MA) and an expansion step of expanding the formed modified region MA. In addition, when energy applied in laser irradiation performed once exceeds a certain energy threshold value, a large amount of precipitation of gallium, rising of a precipitation position, and the like are likely to occur. In addition, a case where the energy threshold value is equal between the seed forming step and the expansion step exists. In this case, the pulse energy of the converging points P1 to P6 may be set to be equal in each case (first energy setting). According to this, energy to be applied in a state of being divided into six times may be set to be equal in each case. It is possible to suppress the large amount of precipitation of gallium and the like. In addition, a case where the energy threshold value in the expansion step is higher in comparison to the seed forming step also exists. For example, this corresponds to a case where a variation is unstable until forming the seed of the modified region MA, but the variation is stable after the seed of the modified region MA has been formed. In this case, pulse energy of a converging point on a front side in the traveling direction TD may be set to be smaller than pulse energy of a converging point on a rear side in the traveling direction TD (second energy setting). According to this, a peak output can be set to be larger in the expansion step of the second half in comparison to the seed forming step of the first half. It is possible to efficiently expand the modified region MA. In addition, a case where the energy threshold value is higher in the seed forming step in comparison to the expansion step also exists. For example, this corresponds to a case where higher energy is required for formation of the seed of the modified region MA in comparison to expansion of the modified region MA. In this case, the pulse energy of the converging point on a front side in the traveling direction TD may be set to be larger than the pulse energy of the converging point on a rear side in the traveling direction TD (third energy setting). According to this, the peak output can be set to be larger in the seed forming step of the first half in comparison to the expansion step of the second half. It is possible to efficiently form the seed of the modified region MA.

In the substrate manufacturing apparatus 1, it is possible to measure the size of the modified region MA during forming one modified layer (FIG. 5, step S15). In addition, in a case where the size of the modified region MA is smaller than the allowable range, it is possible to increase the integrated amount of energy to be applied to the modified region MA by increasing the number of the converging points (step S17). On the other hand, in a case where the size of the modified region MA is larger than the allowable range, it is possible to reduce the integrated amount of energy to be applied to the modified region MA by decreasing the number of the converging points (step S18). It is possible to form the modified region MA having an appropriate size by in-situ feedback control.

### Second Embodiment

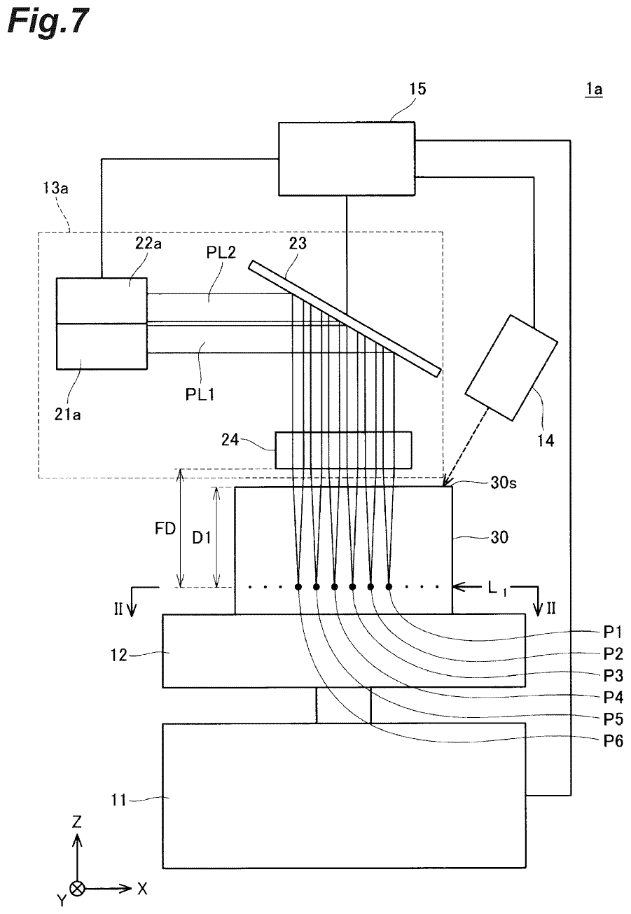

A substrate manufacturing apparatus 1a of a second embodiment (FIG. 7) is different from the substrate manufacturing apparatus 1 of the first embodiment (FIG. 1) in that a plurality of laser light sources 21a to 22a are provided. The same reference numeral will be given to portion common to the substrate manufacturing apparatus 1 of the first embodiment, and description thereof will be omitted.

An irradiation unit 13a includes the laser light source 21a to 22a. Converging points P1 to P3 are formed by modulating pulsed laser PL1 output from the laser light source 21a. Converging points P4 to P6 are formed by modulating pulsed laser PL2 output from the laser light source 22a. The pulsed laser PL1 and the pulsed laser PL2 have the same oscillation frequency and wavelength, but are different in a pulse width. Accordingly, the converging points P1 to P3 and the converging points P4 to P6 are different in the pulse width. In addition, the spatial optical modulator 23 modulates the pulsed laser PL1 and the pulsed laser PL2 so that each pulse energy of the converging points P1 to P6 is the same.

Various settings of the pulse width can be made. For example, a pulse width of the converging points P1 to P6 may be set to be equal (first pulse width setting). A pulse width of converging points P1 to P3 on a front side in the traveling direction TD may be set to be smaller than a pulse width of converging points P4 to P6 on a rear side in the traveling direction TD (second pulse width setting). The pulse width of the converging points P1 to P3 may be set to be larger than the pulse width of the converging points P4 to P6 (third pulse width setting). Since the peak output [W] is calculated by dividing the pulse energy [J] by a pulse width [s], in a case where the pulse energy is constant, as the pulse width is set to be smaller, the peak output can be set to be larger.

As described above, when the energy to be applied in laser irradiation performed once exceeds an energy threshold value, a large amount of precipitation of gallium and the like are likely to occur. In addition, a case where the energy threshold value is equal between the seed forming step and the expansion step exists. In this case, the pulse width of the converging points P1 to P6 may be set to be equal in each case (first pulse width setting). According to this, energy to be applied in a state of being divided into six times may be set to be equal in each case.

In addition, a case where the energy threshold value is higher in the seed forming step in comparison to the expansion step also exists. In this case, the pulse width of the converging points P1 to P3 on the front side in the traveling direction TD may be set to be smaller than the pulse width of the converging points P4 to P6 on the rear side (second pulse width setting). According to this, the peak output can be set to be larger in the seed forming step in the first half in comparison to the expansion step in the second half. It is possible to efficiently form the seed of the modified region MA.

In addition, a case where the energy threshold value is higher in the expansion step in comparison to the seed forming step also exists. In this case, when the pulse width of the converging points P1 to P3 on the front side is set to be larger than the pulse width of the converging points P4 to P6 on the rear side (third pulse width setting). According to this, the peak output can be set to be larger in the expansion step in the second half in comparison to the seed forming step in the first half. It is possible to efficiently expand the modified region MA.

When irradiating the same irradiation point with the pulsed laser a predetermined number of times, it is difficult to change the pulse width. For example, as in the second embodiment, consideration will be given to a case where irradiation with the pulsed laser is performed six times for each irradiation point by setting a pulse period to 0.02 ins. In this case, it is necessary to change the pulse width in a period of 0.1 ins, but it is difficult to perform this control for a laser light source. On the other hand, in the substrate manufacturing apparatus 1a of the second embodiment, a plurality of laser light sources different in the pulse width may be provided. According to this, it is possible to irradiate the same irradiation point with a plurality of converging points having pulse widths different from each other.

### Modification Example

Hereinbefore, the examples of the invention have been described in detail, but the examples are illustrative only and are not intended to limit the appended claims. Technologies described in the appended claims include various modifications and changes of the above-described specific examples.

In the second embodiment, description has been given of a case where the pulse width is set to be different between the laser light source 21a and the laser light source 22a, but there is no limitation to the embodiment, and various parameters may be set to be different. For example, a wavelength may be set to be different between the laser light source 21a and the laser light source 22a. When the wavelength is set to be different, an absorption coefficient of GaN can be made different. Note that, since GaN absorbs a laser with a wavelength shorter than 362 nm, it is necessary to employ a wavelength longer than the wavelength. The wavelength can be set to various wavelengths. For example, the wavelength of the converging points P1 to P6 may be set to be equal in each case (first wavelength setting). The wavelength of the converging points P1 to P3 on the front side in the traveling direction TD may be set to be larger than the wavelength of the converging points P4 to P6 on the rear side (second wavelength setting). The wavelength of the converging points P1 to P3 may be set to be smaller than the wavelength of the converging points P4 to P6 (third wavelength setting). Note that, whether to use which wavelength setting can be appropriately determined in correspondence with a variation in the absorption coefficient of GaN with respect to a wavelength.

In the present disclosure, description has been given of a case where any one of the pulse energy, the pulse width, and the wavelength is set to be different among the plurality of converging points, but there is no limitation to the aspect. Two or more of the pulse energy, the pulse width, and the wavelength may be set to be different. For example, the pulse energy of the converging points P1 to P3 may be set to be smaller than the pulse energy of the converging points P4 to P6, and the pulse width of the converging points P1 to P3 may be set to be larger than the pulse width of the converging points P4 to P6. According to this, the peak output can be set to be larger in the expansion step in the second half in comparison to the seed forming step in the first half.

In addition, a parameter set to be different among the plurality of converging points are not limited to the pulse energy, the pulse width, and the wavelength, and may be various. For example, a pulse waveform may be set to be different.

The technology of the present disclosure is not limited to gallium nitride (GaN), and is applicable to formation of substrates of various compound semiconductors. For example, the technology is applicable to formation of substrates of different kinds of nitride semiconductors such as aluminum nitride (AlN) and indium nitride (InN).

Numerical values in the present disclosures are illustrative only, and are not limited to the above-described values. That is, the number of the scanning lines SL1 to SL6 in FIG. 3 is an example. The number of the modified layers or the substrate layers in FIG. 6 is an example. The period, the predetermined pitch PP, and the peak output value of the pulsed laser are examples. In the substrate manufacturing apparatus 1a of the second embodiment (FIG. 7), the number of the laser light sources is not limited to two, and may be three or more.

The technical elements described in this specification or the drawings exhibit technical usefulness alone or in various combinations, and are not limited to a combination described in the appended claims at the time of filing. In addition, the technologies exemplified in this specification or the drawings can simultaneously achieve a plurality of purposes, and achieving one of the purposes has technical usefulness.

### REFERENCE SIGNS LIST

1, 1a: substrate manufacturing apparatus, 11: stage drive unit, 12: stage, 13: irradiation unit, 14: measurement unit, 15: controller, 21: laser light source, 23: spatial optical modulator, 24: converging lens, 30: ingot, MA: modified region, P1 to P6: converging point, PP: predetermined pitch.

1. A substrate manufacturing apparatus, comprising:
a stage on which a semiconductor substrate is disposed;
an irradiation unit that irradiates the semiconductor substrate disposed on the stage with a pulsed laser of a predetermined pulse period; and
a controller that controls a relative position between the stage and the irradiation unit,
wherein the irradiation unit generates a plurality of converging points arranged on a straight line at a predetermined pitch,
the controller moves the relative position between the stage and the irradiation unit at a predetermined speed in parallel to the straight line on which the plurality of converging points are arranged, and
the predetermined speed is a speed at which a moving distance of the plurality of converging points in one period of the predetermined pulse period is the same as the predetermined pitch.

2. The substrate manufacturing apparatus according to claim 1,
wherein the irradiation unit includes a plurality of laser light sources, and
the plurality of converging points are generated by the plurality of laser light sources.

3. The substrate manufacturing apparatus according to claim 1,
wherein pulse energy of some converging points among the plurality of converging points is different from pulse energy of the other converging points.

4. The substrate manufacturing apparatus according to claim 3,
wherein among the plurality of converging points, pulse energy of converging points on a front side in a traveling direction along which the plurality of converging points are moved by the controller is smaller than pulse energy of converging points on a rear side in the traveling direction.

5. The substrate manufacturing apparatus according to claim 3,
wherein among the plurality of converging points, pulse energy of converging points on a front side in a traveling direction along which the plurality of converging points are moved by the controller is larger than pulse energy of converging points on a rear side in the traveling direction.

6. The substrate manufacturing apparatus according to claim 1,
wherein a pulse width of some converging points among the plurality of converging points is different from a pulse width of the other converging points.

7. The substrate manufacturing apparatus according to claim 6,
wherein among the plurality of converging points, the pulse width of converging points on a front side in a traveling direction along which the plurality of converging points are moved by the controller is smaller than the pulse width of converging points on a rear side in the traveling direction.

8. The substrate manufacturing apparatus according to claim 6,
wherein among the plurality of converging points, the pulse width of converging points on a front side in a traveling direction along which the plurality of converging points are moved by the controller is larger than the pulse width of converging points on a rear side in the traveling direction.

9. The substrate manufacturing apparatus according to claim 1,
wherein a wavelength of some converging points among the plurality of converging points is different from a wavelength of the other converging points.

10. The substrate manufacturing apparatus according to claim 9,
wherein among the plurality of converging points, the wavelength of converging points on a front side in a traveling direction along which the plurality of converging points are moved by the controller is larger than the wavelength of converging points on a rear side in the traveling direction.

11. The substrate manufacturing apparatus according to claim 9,
wherein among the plurality of converging points, the wavelength of converging points on a front side in a traveling direction along which the plurality of converging points are moved by the controller is smaller than the wavelength of converging points on a rear side in the traveling direction.

12. The substrate manufacturing apparatus according to claim 1, further comprising:
a measurement unit that measures a modified region formed in the semiconductor substrate disposed on the stage by the plurality of converging points,
wherein the irradiation unit controls the number of the plurality of converging points in correspondence with a measurement result obtained by the measurement unit.

13. The substrate manufacturing apparatus according to claim 12,
wherein the measurement unit measures a size of the modified region, and
the irradiation unit performs control so that the number of the plurality of converging points further increases as the size of the modified region is smaller.
